(19) United States
(12) Patent Application Publication
(10) Pub. No.: US 2006/0166415 A1
(43) Pub. Date: Jul. 27, 2006

(54) Two-transistor tri-state inverter

(75) Inventors: Themistokles Afentakis, Vancouver, WA (US); Apostolos T. Voutsas, Portland, OR (US); Paul J. Schuele, Washougal, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/387,626

(22) Filed: Mar. 23, 2006

Related U.S. Application Data
(63) Continuation-in-part of application No. 10/862,761, filed on Jun. 7, 2004.
(63) Continuation-in-part of application No. 10/953,913, filed on Sep. 28, 2004, now abandoned.
(63) Continuation-in-part of application No. 11/184,699, filed on Jul. 18, 2005.

(51) Int. Cl. H01L 21/84; H01L 21/00

(52) U.S. Cl. 438/151

(57) ABSTRACT

A two-transistor tri-state inverter is provided, made from a NMOS dual-gate thin-film transistor (DG-TFT) having a top gate, a back gate, and source/drain regions. A PMOS DG-TFT also has a top gate, a back gate, and S/D regions, and the NMOS first S/D region is connected to a PMOS first S/D region. The NMOS top gate is connected to an input signal (Vin), the back gate is connected to a control signal (Vb), the first S/D region supplies an output signal (Vout), and a second S/D region is connected to a reference voltage. The PMOS top gate is connected to the input signal, the back gate is connected to an inverted control signal (−Vb), and a second S/D region is connected to a supply voltage having a higher voltage than the reference voltage.

### RELATED APPLICATIONS

This application is a continuation-in-part of a pending patent application entitled, MULTI-PLANAR LAYOUT VERTICAL THIN-FILM TRANSISTOR INVERTER, Schuele et al., Ser. No. 10/862,761, filed Jun. 7, 2004, Attorney Docket No. SLA0875, which is a continuation-in-part of an issued patent application entitled, VERTICAL THIN FILM TRANSISTOR, invented by Schuele et al., U.S. Pat. No. 6,995,053, filed Apr. 23, 2004, Attorney Docket No. SLA0874.

This application is a continuation-in-part of a pending patent application entitled, DUAL-GATE THIN-FILM TRANSISTOR, invented by Schuele et al., Ser. No. 10/953,913, filed Sep. 28, 2004, Attorney Docket No. SLA0909.

This application is a continuation-in-part of a pending patent application entitled, DUAL-GATE TRANSISTOR DISPLAY, invented by Afentakis et al., Ser. No. 11/184,699, filed Jul. 18, 2005, Attorney Docket No. SLA8010.

### BACKGROUND OF THE INVENTION

1. Field of the Invention

This invention generally relates to integrated circuit (IC) fabrication and, more particularly, to a tri-state inverter, made with only two transistors, and a corresponding fabrication process.

2. Description of the Related Art

FIG. 1 is a diagram depicting the two prevalent CMOS implementations of a tri state inverter (prior art). The CMOS inverter is a major component used in almost all digital MOS circuits. This circuit is composed of two complementary active devices, a NMOS and a PMOS transistor. The circuit performs a two's complement logical operation on the digital signal (logic level) that is received at its input. With a high input signal, the output voltage in zero, while a zero input voltage produces a high voltage at the output. A special type of inverter, widely used in sequential digital circuits, is the tri-state inverter. This circuit has an additional control signal input. When the control signal (Vb) is low, the operation of the tri-state inverter is identical to that of the conventional inverter. When the control signal is high, the inverter is effectively disconnected from the output. In this manner, changes in the input do not affect the output, and inverter output node is seen as having a very high value of impedance.

Tri-state inverters find widespread use as sub-circuit components in shift registers, sample and hold circuits, buffers for IC pads, and many other applications. As with all digital circuits, it is important maximize the level of performance of this inverter block per unit area. One effective way to do this is to minimize the area the circuit occupies. However, transistors can only be as small as the smallest resolution process features.

It would be advantageous if the size of a tri-state inverter circuit could be reduced by using transistors with greater functionality.

It would be advantageous if an inverter circuit could be made with transistors having built-in control functionality, to reduce the total number of transistors needed to build a tri-state inverter circuit.

### SUMMARY OF THE INVENTION

The present invention utilizes dual-gate thin film transistors to realize a tri-state inverter circuit that requires only two transistors, thus reducing the circuit-occupied area by roughly 50%. Since many circuits, such as shift registers and liquid crystal display (LCD) display driver circuits, incorporate a large numbers of tri-state inverters, the benefits of this approach are substantial.

Accordingly, a two-transistor tri-state inverter is provided. The tri-state inverter is made from a NMOS dual-gate thin-film transistor (DG-TFT) having a top gate, a back gate, and source/drain regions. A PMOS DG-TFT also has a top gate, a back gate, and S/D regions, and the NMOS first S/D region is connected to a PMOS first S/D region.

The NMOS top gate is connected to an input signal (Vin), the back gate is connected to a control signal (Vb), the first S/D region supplies an output signal (Vout), and a second S/D region is connected to a reference voltage. The PMOS top gate is connected to the input signal, the back gate is connected to an inverted control signal (−Vb), and a second S/D region is connected to a supply voltage having a higher voltage than the reference voltage.

As explained in more detail below, the back gate of each DG-TFT exerts control over the corresponding channel region. In this manner, a control signal to the back gates can be used to turn the transistors “on” and “off”.

Additional details of the above-described tri-state inverter, a corresponding fabrication process, and a method for tri-stating a complementary metal-oxide semiconductor (CMOS) inverter using only two transistors are presented below.

### BRIEF DESCRIPTION OF THE DRAWINGS

FIG. 1 is a diagram depicting the two prevalent CMOS implementations of a tri state inverter (prior art).

FIG. 2 is a partial cross-sectional view of an exemplary dual-gate thin-film transistor (DG-TFT).

FIG. 3 is a schematic diagram depicting a two-transistor tri-state inverter.

FIG. 4 is a plan view of the NMOS DG-TFT of FIG. 3.

FIG. 5 is a partial cross-sectional and schematic view, depicting the DG-TFT of FIG. 2 in greater detail.

FIG. 6 is a diagram depicting the operating voltages of the device shown in FIG. 5, enabled as an NMOS DG-TFT.

FIG. 7 is a flowchart illustrating a method for forming a two-transistor tri-state inverter.

FIG. 8 is a flowchart illustrating a method for tri-stating a complementary metal-oxide semiconductor (CMOS) inverter.

### DETAILED DESCRIPTION

FIG. 2 is a partial cross-sectional view of an exemplary dual-gate thin-film transistor (DG-TFT). The DG-TFT 200 has the DG-TFT bottom gate 202 aligned in a first horizontal plane 204. The first S/D region 206 and second S/D region 208 are aligned in a second horizontal plane 210, overlying the first plane 204. The top gate 212 is aligned in a third horizontal plane 214, overlying the second plane 210. A channel region 216 is formed in the second horizontal plane 210, intervening between the first S/D region 206 and the second S/D region 208. The bottom gate 202 has vertical sides 218 and 220, and insulating sidewalls 222 and 224 are formed over the bottom gate vertical sides 218 and 220, respectively. The first S/D region 206 and second S/D region 208 overlie the bottom gate 202, between the bottom gate vertical sides 218 and 220.

It should be noted that FIG. 2 describes one particular embodiment of a DG-TFT. Other DG-TFT devices, both conventional and proprietary (not shown) may also be used to enable the tri-state inverter circuit described below.

FIG. 3 is a schematic diagram depicting a two-transistor tri-state inverter. The tri-state inverter 300 comprises a NMOS DG-TFT 302 having a top gate 304, a back gate 306, and source/drain regions 308 and 310. A PMOS DG-TFT 312 has a top gate 314, a back gate 316, and S/D regions 318 and 320. The NMOS first S/D region 308 is connected to the PMOS first S/D region 318.

The NMOS top gate 304 is connected to an input signal (Vin) on line 322, and the back gate is connected to a control signal (Vb) on line 324. The NMOS first S/D region 308 supplies an output signal (Vout) on line 326, and the second S/D region 310 is connected to a reference voltage on line 328 (e.g., ground). The PMOS top gate 314 is connected to the input signal on line 322, and the back gate 316 is connected to an inverted control signal (−Vb) on line 330. The second S/D region 320 is connected to a supply voltage on line 332 (e.g., Vsupply), having a higher voltage than the reference voltage.

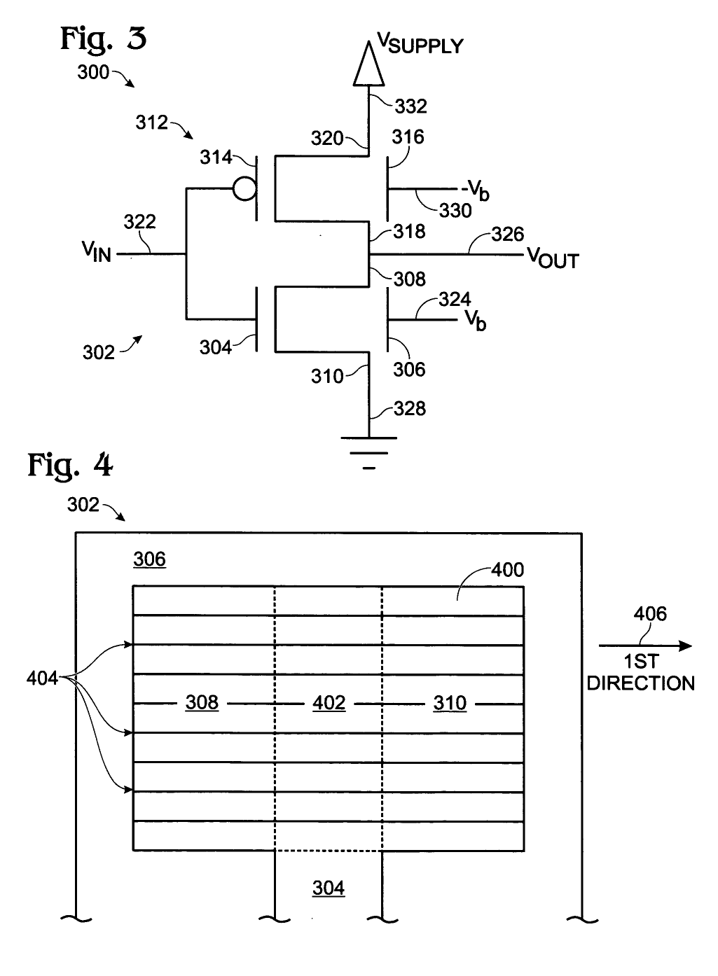

FIG. 4 is a plan view of the NMOS DG-TFT of FIG. 3. The NMOS DG-TFT 302 includes a crystallized Si active layer 400 interposed between the top gate 304 and the back gate 306. The top gate channel 402 and S/D regions 308 and 310 are formed in the crystallized Si active layer 400. In one aspect, the crystallized Si active layer 400 is formed in a single-crystal-like structure having grain boundaries 404 in a first direction 406, parallel to the flow of carriers between the S/D regions 308/310. Although not shown, the PMOS DG-TFT of FIG. 3 may also include a crystallized active Si layer.

### Functional Description

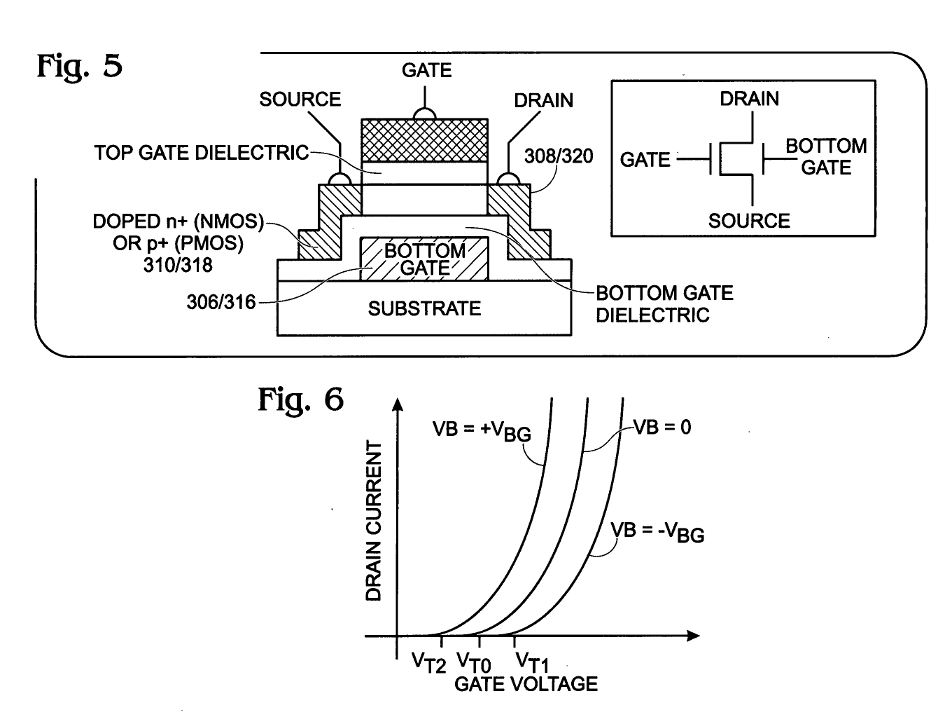

FIG. 5 is a partial cross-sectional and schematic view, depicting the DG-TFT of FIG. 2 in greater detail. As noted above, the two-transistor tri-state inverter utilizes DG-TFTs to minimize the number of transistors required. Specifically, the invention makes use of the fact that the threshold voltage of a DG-TFT can be modulated by the applied bias at the back gate terminal. Note, the back gate can also be referred to as a secondary or bottom gate. Consequently, the transistor can be switched from normal digital operation (ON/OFF mode) to an always-high-impedance mode by the back gate bias.

When a zero bias is applied at the back gate, the transistor operates as a conventional TFT, with a threshold voltage V_{T0}. A negative bias (−V_{BG}) at the back gate pushes the whole channel region into accumulation (further away from depletion). A larger bias is required by the top gate to invert the surface, as compared to the situation when a zero bias is applied to the back gate. Therefore, the threshold voltage of the device increases to a value V_{T1}>V_{T0}. Inversely, a positive bias (+V_{BG}) at the back gate pushes the channel into depletion earlier. Thus, a lower voltage at the top gate is required to invert the channel (pushing it into depletion), which is reflected in a threshold voltage decrease of V_{T2}<V_{T0}.

FIG. 6 is a diagram depicting the operating voltages of the device shown in FIG. 5, enabled as an NMOS DG-TFT. The horizontal axis is top gate voltage. Although not specifically shown, the operation of a PMOS DG-TFT (with p+ doped drain and source regions) is analogous to the operation of the NMOS device. A positive bias at the back gate of a PMOS DG-TFT opposes the onset of depletion by the top gate, increasing the threshold voltage of the device (i.e., making it more negative). A negative back gate bias decreases the threshold voltage (i.e., making it less negative).

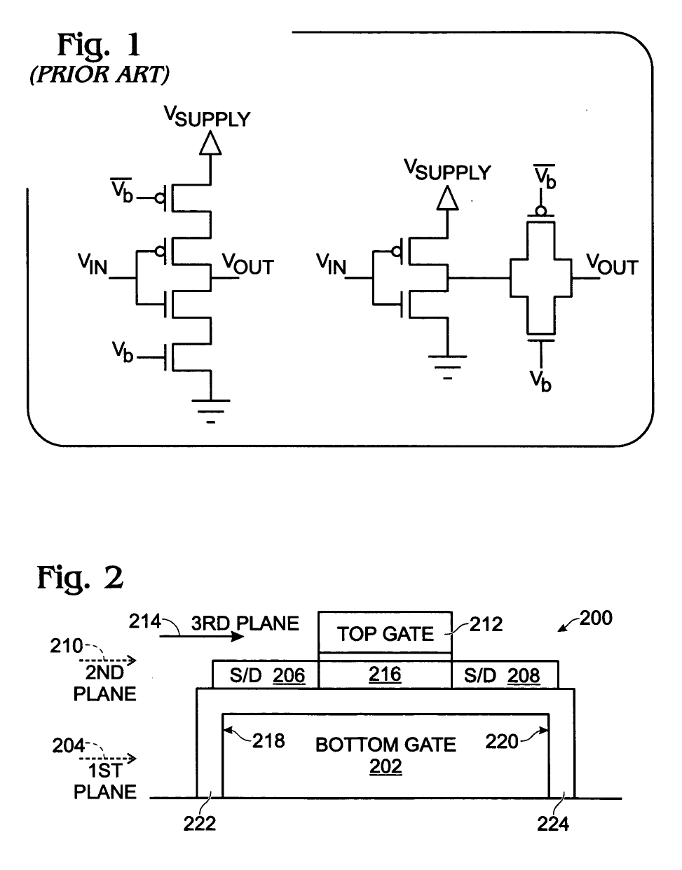

The tri-state inverter uses an NMOS and a PMOS DG-TFT (FIG. 3), so that the control transistors of a convention tri-state inverter (FIG. 1) are not needed. In this manner, the two NMOS and the two PMOS transistors of a conventional tri-state inverter are replaced by one NMOS and one PMOS DG-TFT. The input signal is applied to the top gate of each DG-TFT, and the control signal (Vb) is applied to the back gate.

With a zero applied bias at the back gate of the transistors (V_{b}=0), both active devices perform as conventional TFT structures, and the circuit operates as a CMOS inverter, with Vₒᵤₜ=\overline{Vᵢₙ}. The operation of the inverter is not altered when a positive control bias is applied (V_{b}>0, and −V_{b}<0). This is because the threshold voltage of the NMOS becomes less positive (see FIG. 6), while the threshold voltage of the PMOS becomes less negative. Thus, the inverter is still able to respond to the input signal Vᵢₙ.

In the case of a sufficiently low or negative control bias (V_{b}<0, −V_{b}>0), the threshold voltage of the PMOS becomes more negative, and the threshold voltage of the NMOS more positive, and the following conditions are satisfied:
V_{in,high}<V_{THN}
V_{supply}−V_{in,low}<V_{THP}

where V_{THN} and V_{THP} are the new NMOS and PMOS threshold voltages, and V_{in,high} and V_{in,low} are the high and low voltage levels of Vᵢₙ, respectively (a square waveform for Vᵢₙ has been assumed). This means that the transistors are not able to respond to Vᵢₙ as both transistors are OFF, and the output is at a high impedance (high Z) state. The operation of the tri-state inverter is summarized in Table 1.

TABLE 1
Tri-State Logic

| Vᵢₙ logic | | |
|---|---|---|
| level | V_{b} | Vₒᵤₜ |
| 0 | High | 1 |
| 1 | High | 0 |
| 0 | Low | High Z |
| 1 | Low | High Z |

Although the present invention design may appear simple in retrospect, it serves a very specialized operation, finding application as an interface for analog/digital ports, and as a building block for certain combinational logic digital circuits. The invention is not merely an extension of conventional dual-gate transistor structures, since there is no history of using dual-gate devices for operations, or in the device combination of circuit described herein.

In order to perform the desired operation, a precise optimization process is required for determining the present invention dual-gate transistor geometry (e.g., channel length and channel width) and characteristics (e.g., carrier mobility and threshold voltage), as well as the levels for the secondary gate bias Vb. An example of this approach is presented below. That is, two conventional dual-gate transistors cannot simply be connected to make a tri-state inverter. Rather, a tri-state version of a DG-TFT is necessary to enable the present invention.

For example, in order to optimize the operation of the circuit, the value of the secondary gate bias Vb for normal inverter operation is first selected. This value can be equal to zero if the dual-gate transistors have optimized threshold voltages, so that the switching point of the inverter (the input voltage bias at which the current through the two transistors is maximized) is at half the supply voltage. This level of switching voltage is desired for a number of reasons, such as optimized switching speed and minimum power consumption. Alternately, if the fabricated DG-TFTs do not exhibit a well-balanced switching voltage because of other design tradeoffs, the value of Vb for normal inverter operation can be engineered to compensate.

In order to achieve the minimum propagation delay in normal inverter operation, it is necessary to minimize parasitic effects such as parasitic coupling between the secondary gate and the transistors' active region. For example, the coupling may be minimized between region 306 and regions 310 and 308 of the NMOS device, and region 316 and regions 318 and 320 of the PMOS device, see FIGS. 3 and 5. This result can be achieved by using a shorter bottom gate that does not overlap (horizontally extend past) the top gate electrode.

In this manner, the transient characteristics of the circuit are enhanced if necessary, without a penalty in operation. A shorter bottom gate limits the influence of the bottom gate on the device threshold voltage: only negative (positive) threshold voltage shifts are possible in an NMOS (PMOS) device. This is not a problem though, since for a high-impedance output, the device thresholds are switched in this direction by Vb. The magnitude of Vb for high impedance operation is engineered in conjunction with the bottom gate dielectric thickness, to produce the desired threshold voltage shift.

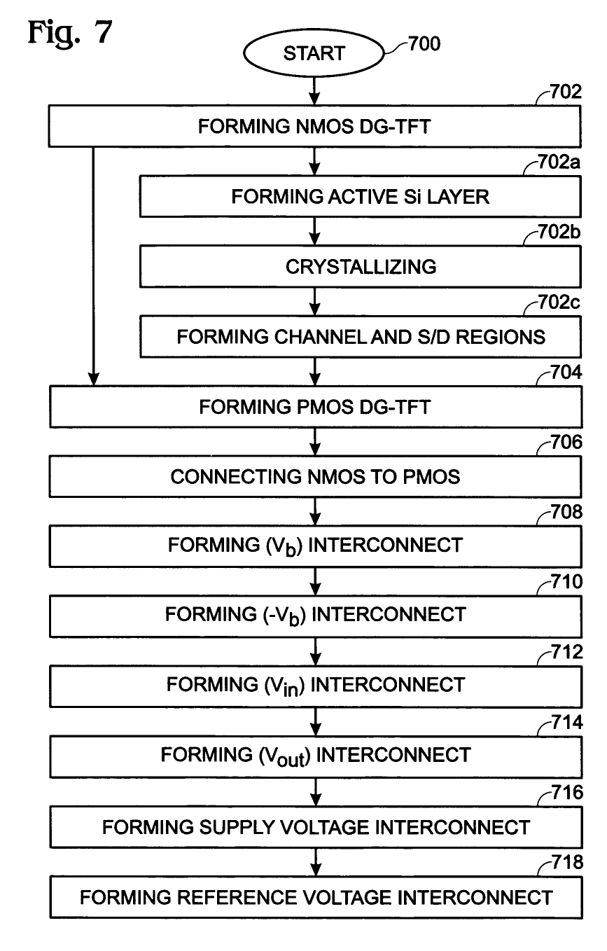

FIG. 7 is a flowchart illustrating a method for forming a two-transistor tri-state inverter. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 700.

Step 702 forms an NMOS DG-TFT with a top gate, a back gate, and S/D regions. Step 704 forms a PMOS DG-TFT with a top gate, a back gate, and S/D regions. Step 706 connects an NMOS first S/D region with a PMOS first S/D region. Step 708 forms a control voltage (Vb) interconnect to the NMOS back gate. Step 710 forms an inverted control voltage (−Vb) interconnect to the PMOS back gate. Step 712 forms an input signal (Vin) interconnect to the NMOS top gate and the PMOS top gate. Step 714 forms an output signal (Vout) interconnect to the NMOS first S/D region. Step 716 forms a supply voltage interconnect to a PMOS second S/D region, and Step 718 forms a reference voltage interconnect to an NMOS second S/D region, where the reference voltage is lower in voltage than the supply voltage. As noted above, some steps may be performed concurrently or in a different order than implied by the step numbering.

In one aspect, forming an NMOS DG-TFT with the top gate, back gate, and S/D regions in Step 702 includes substeps. Step 702a forms an active Si layer interposed between the top gate and the bottom gate. Step 702b crystallizes the active Si layer. Step 702c forms top gate channel and S/D regions in the active Si layer. In another aspect, crystallizing the active Si layer in Step 702b includes substeps (not shown). Step 702b1 irradiates portions of the active Si layer in a stepping sequence, with a first laser beam having a wavelength in the range of about 200 nanometers (nm) to about 600 nm. Step 702b2 melts the active Si layer. Step 702b3 transforms the active Si layer to polycrystalline Si.

In a different aspect, Step 702 and 704 form the NMOS and PMOS DG-TFTs, respectively, on a substrate top surface, where the substrate is a material such as glass, plastic, or quartz. Then, crystallizing the active Si layer in Step 702b may include additional substeps (not shown). Step 702b4 irradiates a substrate bottom surface with a second laser beam, and Step 702b5 heats the substrate with the second laser beam simultaneously with the melting of the active Si layer with the first laser beam (Step 702b2). In one aspect, the second laser beam has a wavelength in the range of about 9 to 11 micrometers (μm). For example, a CO₂-gas laser can be used.

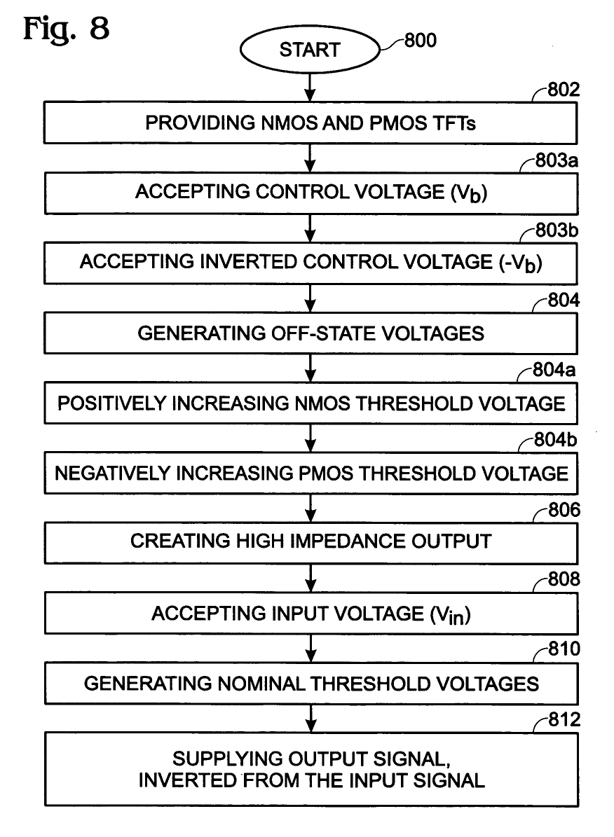

FIG. 8 is a flowchart illustrating a method for tri-stating a complementary metal-oxide semiconductor (CMOS) inverter. The method starts at Step 800. Step 802 provides a circuit that consists exclusively of an NMOS thin-film transistor (TFT) series-connected to a PMOS TFT. Step 804 generates NMOS and PMOS TFT off-state threshold voltages (Vt1). Step 806 creates a high impedance inverter output in response to the off-state threshold voltages. Step 808 accepts an input signal (Vin) at an inverter input. Step 810 generates NMOS and PMOS TFT nominal threshold voltages (Vt0), less than the off-state threshold voltages. Step 812 supplies an output signal (Vout) from the inverter output, inverted from the input signal, in response to the nominal threshold voltages.

In one aspect, Step 803a accepts a control voltage (Vb), and Step 803b accepts an inverted control voltage (−Vb). Then, generating the off-state threshold voltages in Step 804 includes substeps. Step 804a positively increases (makes more positive) the NMOS TFT threshold voltage in response to the control voltage. Step 804b negatively increases (makes more negative) the PMOS TFT threshold voltage in response to the inverted control voltage.

In another aspect, providing the NMOS TFT series-connected to the PMOS TFT in Step 802 includes substeps (not shown). Step 802a provides a NMOS DG-TFT having a top gate connected to the inverter input, a back gate, and source/drain regions. Step 802b provides a PMOS DG-TFT having a top gate connected to the inverter input, a back gate, and S/D regions, where the NMOS first S/D region is connected to a PMOS first S/D region and the inverter output.

In this aspect, Step 804a positively increases the NMOS DG-TFT threshold voltage in response accepting the control voltage at the NMOS DG-TFT back gate. Likewise, Step 804b negatively increases the PMOS DG-TFT threshold voltage in response to accepting the inverted control voltage at the PMOS DG-TFT back gate.

In another aspect, generating NMOS and PMOS TFT nominal threshold voltages in Step 810 includes substeps (not shown). Step 810a accepts a control voltage at the NMOS back gate greater than, or equal to about 0 volts. Step 810b accepts an inverted control voltage at the PMOS back gate less than, or equal to about 0 volts.

Likewise, increasing the NMOS TFT threshold voltage in response to the control voltage in Step 804a includes accepting a control voltage less than about 0 volts. Increasing the PMOS TFT threshold voltage in response to the inverted control voltage in Step 804b includes accepting an inverted control voltage of more than about 0 volts.

A two-transistor tri-state inverter has been presented, along with some associated fabrication details and methods of use. Examples of particular voltages have been used to illustrate the invention. However, the invention is not limited to merely these examples. Other variations and embodiments of the invention will occur to those skilled in the art.

We claim:

1. A method for forming a two-transistor tri-state inverter, the method comprising:
forming an NMOS dual-gate thin-film transistor (DG-TFT) with a top gate, a back gate, and source/drain (S/D) regions;
forming a PMOS DG-TFT with a top gate, a back gate, and S/D regions; and,
connecting an NMOS first S/D region with a PMOS first S/D region.

2. The method of claim 1 further comprising:
forming a control voltage (Vb) interconnect to the NMOS back gate; and,
forming an inverted control voltage (−Vb) interconnect to the PMOS back gate.

3. The method of claim 2 further comprising:
forming an input signal (Vin) interconnect to the NMOS top gate and the PMOS top gate; and,
forming an output signal (Vout) interconnect to the NMOS first S/D region.

4. The method of claim 3 further comprising:
forming a supply voltage interconnect to a PMOS second S/D region; and,
forming a reference voltage interconnect to an NMOS second S/D region, where the reference voltage is lower in voltage than the supply voltage.

5. The method of claim 1 wherein forming an NMOS DG-TFT with the top gate, back gate, and S/D regions includes:
forming an active Si layer interposed between the top gate and the bottom gate;
crystallizing the active Si layer; and,
forming top gate channel and S/D regions in the active Si layer.

6. The method of claim 5 wherein crystallizing the active Si layer includes:
irradiating portions of the active Si layer in a stepping sequence, with a first laser beam having a wavelength in the range of about 200 nanometers (nm) to about 600 nm;
melting the active Si layer; and,
transforming the active Si layer to polycrystalline Si.

7. The method of claim 6 further comprising:
forming the NMOS and PMOS DG-TFTs on a substrate top surface, where the substrate is selected from a group consisting of glass, plastic, and quartz; and,
wherein crystallizing the active Si layer includes:
irradiating a substrate bottom surface with a second laser beam; and,
heating the substrate with the second laser beam simultaneously with the melting of the active Si layer with the first laser beam.

8. The method of claim 7 wherein irradiating the substrate bottom surface includes irradiating with a second laser beam having a wavelength in the range of about 9 to 11 micrometers (μm).

9. The method of claim 7 wherein irradiating the substrate bottom surface includes irradiating with a CO₂-gas laser.

10. A two-transistor tri-state inverter, the tri-state inverter comprising:
a NMOS dual-gate thin-film transistor (DG-TFT) having a top gate, a back gate, and source/drain regions;
a PMOS DG-TFT having a top gate, a back gate, and S/D regions; and,
wherein an NMOS first S/D region is connected to a PMOS first S/D region.

11. The tri-state inverter of claim 10 wherein the NMOS top gate is connected to an input signal (Vin), the back gate is connected to a control signal (Vb), the first S/D region supplies an output signal (Vout), and a second S/D region is connected to a reference voltage; and,
wherein the PMOS top gate is connected to the input signal, the back gate is connected to an inverted control signal (−Vb), and a second S/D region is connected to a supply voltage having a higher voltage than the reference voltage.

12. The tri-state inverter of claim 10 wherein the NMOS DG-TFT includes:
a crystallized Si active layer interposed between the top gate and the back gate;
top gate channel and S/D regions formed in the crystallized Si active layer.

13. The tri-state inverter of claim 12 wherein the crystallized Si active layer is formed in a single-crystal-like structure having grain boundaries in a first direction, parallel to a flow of carriers between the S/D regions in a second direction.

14. A method for tri-stating a complementary metal-oxide semiconductor (CMOS) inverter, the method comprising:
providing a circuit consisting of an NMOS thin-film transistor (TFT) series-connected to a PMOS TFT;
generating NMOS and PMOS TFT off-state threshold voltages (Vt1); and,
creating a high impedance inverter output in response to the off-state threshold voltages.

15. The method of claim 14 further comprising:
accepting an input signal (Vin) at an inverter input;
generating NMOS and PMOS TFT nominal threshold voltages (Vt0), less than the off-state threshold voltages; and,
supplying an output signal (Vout) from the inverter output, inverted from the input signal, in response to the nominal threshold voltages.

16. The method of claim 15 further comprising:
accepting a control voltage (Vb);
accepting an inverted control voltage (−Vb); and, wherein generating off-state threshold voltages includes:
positively increasing the NMOS TFT threshold voltage in response to the control voltage; and,
negatively increasing the PMOS TFT threshold voltage in response to the inverted control voltage.

17. The method of claim 16 wherein providing the NMOS TFT series-connected to the PMOS TFT includes providing:
a NMOS dual-gate TFT (DG-TFT) having a top gate connected to the inverter input, a back gate, and source/drain regions;
a PMOS DG-TFT having a top gate connected to the inverter input, a back gate, and S/D regions; and,
wherein an NMOS first S/D region is connected to a PMOS first S/D region and the inverter output.

18. The method of claim 17 wherein generating off-state threshold voltages includes:
positively increasing the NMOS DG-TFT threshold voltage in response accepting the control voltage at the NMOS DG-TFT back gate; and,
negatively increasing the PMOS DG-TFT threshold voltage in response to accepting the inverted control voltage at the PMOS DG-TFT back gate.

19. The method of claim 18 wherein generating NMOS and PMOS TFT nominal threshold voltages includes:
accepting a control voltage at the NMOS back gate greater than, or equal to about 0 volts; and, accepting an inverted control voltage at the PMOS back gate less than, or equal to about 0 volts.

20. The method of claim 19 wherein increasing the NMOS TFT threshold voltage in response to the control voltage includes accepting a control voltage less than about 0 volts; and,
wherein increasing the PMOS TFT threshold voltage in response to the inverted control voltage includes accepting an inverted control voltage of more than about 0 volts.
